(19) United States
(12) Patent Application Publication
(10) Pub. No.: US 2015/0102308 A1
(43) Pub. Date: Apr. 16, 2015

(54) ORGANIC SEMICONDUCTOR LAYER, ELECTRONIC DEVICE, AND METHOD FOR MANUFACTURING ELECTRONIC DEVICE

(71) Applicant: Sony Corporation, Tokyo (JP)

(72) Inventors: Norihito Kobayashi, Kanagawa (JP); Eri Igarashi, Kanagawa (JP)

(73) Assignee: Sony Corporation, Tokyo (JP)

(21) Appl. No.: 14/391,862

(22) PCT Filed: Apr. 5, 2013
(86) PCT No.: PCT/JP2013/060539

§ 371 Date: Oct. 10, 2014

(30) Foreign Application Priority Data
Apr. 17, 2012 (JP) 2012-093869

(51) Int. Cl. H01L 51/00; H01L 51/05

(52) U.S. Cl. CPC H01L 51/0073; H01L 51/0094; H01L 51/0512; H01L 51/0003
USPC 257/40; 252/500; 438/99

(57) ABSTRACT

Provided is an organic semiconductor layer including a mixture of a first polycyclic aromatic hydrocarbon to which a substituent R₁ other than a hydrogen atom is bonded by a single bond, and a second polycyclic aromatic hydrocarbon.

### TECHNICAL FIELD

The present disclosure relates to an organic semiconductor layer, an electronic device including this organic semiconductor layer, and a method for manufacturing an electronic device.

### BACKGROUND ART

Recently, electronic devices such as semiconductor devices that include a semiconductor layer formed from an organic semiconductor material are drawing a lot of attention. Such an electronic device allows a semiconductor layer to be formed at a lower temperature than a structure that includes a semiconductor layer formed from an inorganic material. Consequently, plastics and other such materials that have low heat resistance but are flexible can be formed on a substrate, leading to the expectation increased functionality as well as reduced costs.

Currently, as an organic semiconductor material constituting a semiconductor layer, for example, an organic semiconductor material having the below-described structural formula, in which at least either the 3-position or the 9-position of 6,12-dioxaanthanthrene (a so-called peri-xanthenoxanthene, 6,12-dioxaanthanthrene, hereinafter sometimes abbreviated to “PXX”) is substituted with a substituent other than hydrogen, is being widely researched (e.g., refer to JP 2010-006794A).

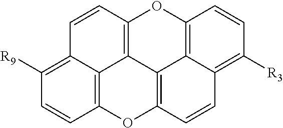

### CITATION LIST

### Patent Literature

Patent Literature 1: JP 2010-006794A

### SUMMARY OF INVENTION

### Technical Problem

The organic semiconductor material having the above-described structural formula disclosed in the above-described patent publication has high carrier mobility, as well as a high level of freedom in molecular design and high process adaptability. However, there is a strong need for a material that exhibits a much higher level of carrier mobility.

Therefore, it is an object of the present disclosure to provide an organic semiconductor layer having a much higher level of carrier mobility, an electronic device including such an organic semiconductor layer, and a method for manufacturing an electronic device.

### Solution to Problem

An organic semiconductor layer according to a first embodiment of the present disclosure for achieving the objective includes a mixture of a first polycyclic aromatic hydrocarbon to which a substituent R₁ other than a hydrogen atom is bonded by a single bond, and a second polycyclic aromatic hydrocarbon.

An organic semiconductor layer according to a second embodiment of the present disclosure for achieving the objective includes a mixture of a first polycyclic aromatic hydrocarbon to which a first substituent R₁ other than a hydrogen atom is bonded by a single bond, and a second polycyclic aromatic hydrocarbon to which a second substituent R₂ other than a hydrogen atom is bonded by a single bond. The first polycyclic aromatic hydrocarbon and the second polycyclic aromatic hydrocarbon are formed from the same polycyclic aromatic hydrocarbon. A binding site of the first substituent R₁ to the first polycyclic aromatic hydrocarbon is different to a binding site of the second substituent R₂ to the second polycyclic aromatic hydrocarbon.

An organic semiconductor layer according to a third embodiment of the present disclosure for achieving the objective includes a mixture of a first polycyclic aromatic hydrocarbon to which a first substituent R₁ other than a hydrogen atom is bonded by a single bond, and a second polycyclic aromatic hydrocarbon to which a second substituent R₂ other than a hydrogen atom is bonded by a single bond. The first polycyclic aromatic hydrocarbon and the second polycyclic aromatic hydrocarbon are formed from the same polycyclic aromatic hydrocarbon. A binding site of the first substituent R₁ to the first polycyclic aromatic hydrocarbon is the same as a binding site of the second substituent R₂ to the second polycyclic aromatic hydrocarbon. The first substituent R₁ and the second substituent R₂ are different.

An electronic device according to the present disclosure for achieving the objective includes at least a first electrode, a second electrode disposed separately from the first electrode, and an active layer provided from the first electrode to the second electrode. The active layer is formed from the organic semiconductor layer according to any one of the first to third embodiments.

There is provided a method for manufacturing an electronic device according to the present disclosure for achieving the objective, the electronic device including at least a first electrode, a second electrode disposed separately from the first electrode, and an active layer provided from the first electrode to the second electrode, the method including forming the active layer by coating and drying a mixed solution formed from a mixture of a first polycyclic aromatic hydrocarbon to which a substituent R₁ other than a hydrogen atom is bonded by a single bond and a second polycyclic aromatic hydrocarbon, or a mixed solution formed from a mixture of a first polycyclic aromatic hydrocarbon to which a first substituent R₁ other than a hydrogen atom is bonded by a single bond and a second polycyclic aromatic hydrocarbon to which a second substituent R₂ other than a hydrogen atom is bonded by a single bond, wherein the first polycyclic aromatic hydrocarbon and the second polycyclic aromatic hydrocarbon are formed from the same polycyclic aromatic hydrocarbon, and wherein a binding site of the first substituent R₁ to the first polycyclic aromatic hydrocarbon is different to a binding site of the second substituent R₂ to the second polycyclic aromatic hydrocarbon, or a mixed solution formed from a mixture of a first polycyclic aromatic hydrocarbon to which a first substituent R₁ other than a hydrogen atom is bonded by a single bond and a second polycyclic aromatic hydrocarbon to which a second substituent R₂ other than a hydrogen atom is bonded by a single bond, wherein the first polycyclic aromatic hydrocarbon and the second polycyclic aromatic hydrocarbon are formed from the same polycyclic aromatic hydrocarbon, wherein a binding site of the first substituent R₁ to the first polycyclic aromatic hydrocarbon is the same as a binding site of the second substituent R₂ to the second polycyclic aromatic hydrocarbon, and wherein the first substituent R₁ and the second substituent R₂ are different.

### Advantageous Effects of Invention

In the present disclosure, since an organic semiconductor layer or an active layer is formed from a mixture of two types of polycyclic aromatic hydrocarbon, a much higher level of carrier mobility is exhibited.

### BRIEF DESCRIPTION OF DRAWINGS

FIGS. 1A and 1B are schematic partial end diagrams of a base and the like for illustrating an outline of the method for manufacturing the electronic device of Working Example 1.

FIGS. 2A and 2B are schematic partial end diagrams of a base and the like for illustrating an outline of the method for manufacturing the electronic device of Working Example 2.

FIGS. 3A and 3B are schematic partial end diagrams of a base and the like for illustrating an outline of the method for manufacturing the electronic device of Working Example 3.

FIGS. 4A, 4B and 4C are schematic partial end diagrams of a base and the like for illustrating an outline of the method for manufacturing the electronic device of Working Example 4.

FIGS. 5A and 5B are schematic partial end diagrams of the electronic device of Working Example 5.

### DESCRIPTION OF EMBODIMENTS

Hereinafter, preferred embodiments of the present invention will be described in detail with reference to the appended drawings. Note that, in this specification and the drawings, elements that have substantially the same function and structure are denoted with the same reference signs, and repeated explanation is omitted. The description will now be made in the following order.

1. Organic semiconductor layer according to the first to third embodiments of the present disclosure, electronic device, method for manufacturing an electronic device, and overall description
2. Working Example 1 (organic semiconductor layer according to the first to third embodiments of the present disclosure, electronic device, and method for manufacturing an electronic device)
3. Working Example 2 (modification of Working Example 1)
4. Working Example 3 (another modification of Working Example 1)
5. Working Example 4 (yet another modification of Working Example 1)
6. Working Example 5 (yet another modification of Working Example 1, a two-terminal type electronic device), and other matters

### [Organic Semiconductor Layer According to the First to Third Embodiments of the Present Disclosure, Electronic Device, Method for Manufacturing an Electronic Device, and Overall Description]

The electronic device according to the present disclosure, or, an electronic device obtained by the method for manufacturing an electronic device according to the present disclosure, can be configured as a so-called two-terminal type electronic device, or alternatively,

can be configured as a mode that includes a first electrode, a second electrode disposed separated from the first electrode, a control electrode, and an insulating layer,

wherein the control electrode is provided facing a portion of the active layer that is positioned between the first electrode and the second electrode via the insulating layer, namely, can be configured as a so-called three-terminal type electronic device.

The organic semiconductor layer according to the first embodiment of the present disclosure in the electronic device of the present disclosure that includes the above-described preferred modes, the organic semiconductor layer according to the first embodiment of the present disclosure in the method for manufacturing the electronic device of the present disclosure that includes the above-described preferred modes, or alternatively, the organic semiconductor layer according to the first embodiment of the present disclosure (hereinafter, these organic semiconductor layers are collectively referred to as “the organic semiconductor layers according to the first embodiment of the present disclosure”), may be configured so that

the first polycyclic aromatic hydrocarbon has a phenyl group, and

the substituent R₁ is bonded the phenyl group. In such a mode, the first polycyclic aromatic hydrocarbon can be formed from 3,9-diphenyl peri-xanthenoxanthene (abbreviated as “Ph-PXX”). Further, in such a mode in which the first polycyclic aromatic hydrocarbon is formed from Ph-PXX, as shown in the following structural formula (1), the first substituent R₁ can be bonded to the respective para-positions of the phenyl group. Here, examples of the first substituent R₁ include one kind of substituent selected from the group consisting of an alkyl group, a cycloalkyl group, an alkenyl group, an alkynyl group, an aryl group, an arylalkyl group, an aromatic heterocycle, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amide group, a carbamoyl group, a ureido group, a sulfinyl group, an alkylsulfonyl group, an arylsulfonyl group, an amino group, a halogen atom, a fluorinated hydrocarbon group, a cyano group, a nitro group, a hydroxy group, a mercapto group, a silyl group, and a trimethyl silyl group.

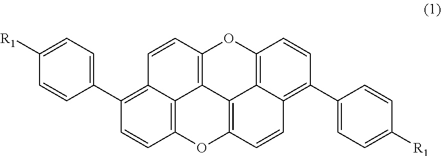

The organic semiconductor layers according to the first embodiment of the present disclosure that includes the above-described preferred modes can be configured so that,

the second polycyclic aromatic hydrocarbon has a phenyl group and a second substituent R₂ bonded to the phenyl group,

wherein the second polycyclic aromatic hydrocarbon having a phenyl group to which the second substituent R₂ is bonded has a different structure to the first polycyclic aromatic hydrocarbon to which the substituent R₁ is bonded by a single bond. It is noted that such a structure will be referred to, for convenience, as “structure 1 of the second polycyclic aromatic hydrocarbon”.

Further, such a structure 1 of the second polycyclic aromatic hydrocarbon can be configured so that,

as shown in the following structural formula (2) or structural formula (3), the second polycyclic aromatic hydrocarbon is formed from 3,9-diphenyl peri-xanthenoxanthene (Ph-PXX), and

the second substituent R₂ is bonded to the respective ortho- or meta-positions of the phenyl group. It is noted that such a structure is, for convenience, referred to as “structure 1A of the second polycyclic aromatic hydrocarbon”. Moreover, the second substituent R₂ can be bonded to the respective ortho- or para-positions of the phenyl group, or the second substituent R₂ can be bonded to the respective meta- or para-positions of the phenyl group. Further, the second substituent R₂ may be the same as or different to the first substituent R₁.

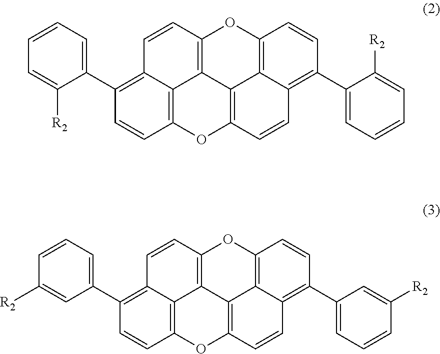

Alternatively, structure 1 of the second polycyclic aromatic hydrocarbon can be configured so that,

the second polycyclic aromatic hydrocarbon is formed from 3,9-diphenyl peri-xanthenoxanthene (Ph-PXX), and the second substituent R₂ is bonded to the respective para-positions of the phenyl group, and

the first substituent R₁ and the second substituent R₂ are different. It is noted that such a structure is, for convenience, referred to as “structure 1B of the second polycyclic aromatic hydrocarbon”.

Alternatively, structure 1 of the second polycyclic aromatic hydrocarbon can be configured so that the second polycyclic aromatic hydrocarbon is formed from 2,8-diphenyl peri-xanthenoxanthene or 1,7-diphenyl peri-xanthenoxanthene. It is noted that such a structure is, for convenience, referred to as “structure 1C of the second polycyclic aromatic hydrocarbon”.

Further, examples of the second substituent R₂ may include a hydrogen atom, or the substituents described above as examples of substituent R₁.

Alternatively, the organic semiconductor layers according to the first embodiment of the present disclosure that includes the above-described preferred modes can be configured so that second polycyclic aromatic hydrocarbon is formed from TIPS-pentacene.

The organic semiconductor layer according to the second embodiment of the present disclosure in the electronic device of the present disclosure that includes the above-described preferred modes, the organic semiconductor layer according to the second embodiment of the present disclosure in the method for manufacturing the electronic device of the present disclosure that includes the above-described preferred modes, or alternatively, the organic semiconductor layer according to the second embodiment of the present disclosure (hereinafter, these organic semiconductor layers are collectively referred to as “the organic semiconductor layers according to the second embodiment of the present disclosure”), may be configured so that the first polycyclic aromatic hydrocarbon and the second polycyclic aromatic hydrocarbon are formed from 3,9-diphenyl peri-xanthenoxanthene (Ph-PXX), the binding site of the first substituent R₁ to the first polycyclic aromatic hydrocarbon is a para-position of a phenyl group constituting the first polycyclic aromatic hydrocarbon, and the binding site of the second substituent R₂ to the second polycyclic aromatic hydrocarbon is an ortho-position or a meta-position of a phenyl group constituting the second polycyclic aromatic hydrocarbon. It is noted that the second substituent R₂ may be bonded to the respective ortho-positions and para-positions of the phenyl group, or the second substituent R₂ may be bonded to the respective meta-positions and para-positions of the phenyl group. Further, the first substituent R₁ and the second substituent R₂ may be the same or different.

Further, the organic semiconductor layer according to the third embodiment of the present disclosure in the electronic device of the present disclosure that includes the above-described preferred modes, the organic semiconductor layer according to the third embodiment of the present disclosure in the method for manufacturing the electronic device of the present disclosure that includes the above-described preferred modes, or alternatively, the organic semiconductor layer according to the third embodiment of the present disclosure (hereinafter, these organic semiconductor layers are collectively referred to as “the organic semiconductor layers according to the third embodiment of the present disclosure”) may be configured so that the first polycyclic aromatic hydrocarbon and the second polycyclic aromatic hydrocarbon are formed from 3,9-diphenyl peri-xanthenoxanthene (Ph-PXX), the binding site of the first substituent R₁ to the first polycyclic aromatic hydrocarbon is a para-position of a phenyl group constituting the first polycyclic aromatic hydrocarbon, and the binding site of the second substituent R₂ to the second polycyclic aromatic hydrocarbon is a para-position of a phenyl group constituting the second polycyclic aromatic hydrocarbon.

In the organic semiconductor layers according to the second embodiment or the third embodiment of the present disclosure that includes the above-described preferred structures, examples of the first substituent R₂ may include the substituents described above as examples of the first substituent R₁. Examples of the second substituent R₂ may include a hydrogen atom, or the substituents described above as examples of the substituent R₁.

In the method for manufacturing the electronic device of the present disclosure that includes the above-described preferred modes and structures, an organic insulating material may be additionally mixed in the mixed solution. Here, examples of the organic insulating material may include poly(α-methylstyrene), a cyclic cycloolefin polymer, or cyclic cycloolefin copolymer. Specific examples of the cyclic cycloolefin polymer or cyclic cycloolefin copolymer include TOPAS (registered trademark, manufactured by Topas Advanced Polymers GmbH), ARTON (registered trademark, manufactured by JSR Corporation), and ZEONOR (registered trademark, manufactured by Zeon Corporation).

The mixing ratio of the first polycyclic aromatic hydrocarbon and the second polycyclic aromatic hydrocarbon is desirably, although not limited to, based on a mass of the first polycyclic aromatic hydrocarbon of “1”, such that the mass of the second polycyclic aromatic hydrocarbon is 0.5 or less, and preferably 0.35 or less.

In the organic semiconductor layer according to the first to third embodiments of the present disclosure that include the above-described preferred modes and structures, the electronic device of the present disclosure, and the method for manufacturing the electronic device of the present disclosure (hereinafter, these are sometimes collectively referred to simply as “the present disclosure”), examples of the alkyl group constituting the substituent R₁, the first substituent R₁, or the second substituent R₂ include a methyl group, an ethyl group, a propyl group, an isopropyl group, an isobutyl group, an isopentyl group, an isohexyl group, a tertiary butyl group, a pentyl group, a hexyl group, an octyl group, a dodecyl group and the like. It is noted that the alkyl group may be linear or branched. Further, examples of the cycloalkyl group may include a cyclopentyl group, a cyclohexyl group and the like; examples of the alkenyl may include a vinyl group and the like; examples of the alkynyl group may include an ethynyl group; examples of the aryl group may include a phenyl group, a naphthyl group, a biphenyl group and the like; examples of the arylalkyl group may include a methyl aryl group, an ethyl aryl group, an isopropyl aryl group, normal butyl aryl group, a p-tolyl group, a p-ethylphenyl group, a p-isopropylphenyl group, a p-iso-butylphenyl group, a 4-propylphenyl group, a 4-butylphenyl group, a 4-nonylphenyl group, and the like; examples of the aromatic heterocycle may include a pyridyl group, a thienyl group, a furyl group, a pyridazinyl group, a pyrimidinyl group, a pyrazinyl group, a triazinyl group, an imidazolyl group, a pyrazolyl group, a thiazolyl group, a quinazolinyl group, a phthalazinyl group and the like; examples of the heterocyclic group may include a pyrrolidyl group, an imidazolidyl group, a morpholinyl group, an oxazolidyl group and the like; examples of the alkoxy group may include a methoxy group, an ethoxy group, a propyloxy group, a pentyloxy group, a hexyloxy group and the like; examples of the cycloalkoxy group may include a cyclopentyl group, a cyclohexyl group and the like; examples of the aryloxy group may include a phenoxy group, a naphthyloxy group and the like; examples of the alkylthio group may include a methylthio group, an ethylthio group, a propylthio group, a pentylthio group, a hexylthio group and the like; examples of the cycloalkylthio group may include a cyclopentylthio group, a cyclohexylthio group and the like; examples of the arylthio group may include a phenylthio group, a naphthylthio group and the like; examples of the alkoxycarbonyl group may include a methyloxycarbonyl group, an ethyloxycarbonyl group, a butyloxycarbonyl group, an octyloxycarbonyl group and the like; examples of the aryloxycarbonyl group may include a phenyloxycarbonyl group, a naphthyloxycarbonyl group and the like; examples of the sulfamoyl group may include an aminosulfonyl group, a methylaminosulfonyl group, a dimethylaminosulfonyl group, a cyclohexylaminosulfonyl group, a phenylaminosulfonyl group, a naphthylaminosulfonyl group, a 2-pyridylaminosulfonyl group and the like; examples of the acyl group may include an acetyl group, an ethylcarbonyl group, a propylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, a pyridylcarbonyl group and the like; examples of the acyloxy group may include an acetyloxy group, an ethylcarbonyloxy group, an octylcarbonyloxy group, a phenylcarbonyloxy group and the like; examples of the amide may include a methylcarbonylamino group, an ethylcarbonylamino group, a dimethylaminocarbonylamino group, a pentylcarbonylamino group, a cyclohexylcarbonylamino group, 2-ethylhexylcarbonylamino group, a phenylcarbonylamino group, a naphthylcarbonylamino group and the like; examples of the carbamoyl group may include an aminocarbamoyl group, a methylaminocarbamoyl group, a dimethylaminocarbamoyl group, a cyclohexylaminocarbamoyl group, a 2-ethylhexylaminocarbamoyl group, a phenylaminocarbamoyl group, a naphthylaminocarbamoyl group, a 2-pyridylaminocarbonyl group and the like; examples of the ureido group may include a methylureido group, an ethylureido group, a cyclohexylureido group, a dodecylureido group, a phenylureido group, a naphthylureido group, a 2-pyridylaminoureido group and the like; examples of the sulfinyl may include a methylsulfinyl group, an ethylsulfinyl group, a butylsulfinyl group, a cyclohexyl sulfinyl group, a 2-ethylhexylsulfinyl group, a phenylsulfinyl group, a naphthylsulfinyl group, a 2-pyridylsulfinyl group and the like; examples of the alkylsulfonyl group may include a methylsulfonyl group, an ethylsulfonyl group, a butylsulfonyl group, a cyclohexylsulfonyl group, a 2-ethylhexylsulfonyl group, a dodecylsulfonyl group and the like; examples of the arylsulfonyl group may include a phenylsulfonyl group, a naphthylsulfonyl group, a 2-pyridylsulfonyl group and the like; examples of the amino group may include an amino group, an ethylamino group, a dimethylamino group, a butylamino group, a 2-ethylhexylamino group, an anilino group, a naphthylamino group, a 2-pyridylamino group and the like; examples of the halogen atom may include a fluorine atom, a chlorine atom, a bromine atom, an iodine atom and the like; and examples of the fluorinated hydrocarbon group may include a fluoromethyl group, a trifluoromethyl group, a pentafluoroethyl group, a pentafluorophenyl group and the like. Further examples may also include a cyano group, a nitro group, a hydroxy group, a mercapto group, a silyl group and the like. Examples of the silyl group a trimethylsilyl group, a triisopropylsilyl group, a triphenylsilyl group, a phenyl group diethylsilyl and the like. Here, the above-described substituents may be further substituted with an above-described substituent. Further, a plurality of these substituents may be joined to each other to form a ring. In addition, an additive (e.g., a so-called doping material, such as an n-type impurity or a p-type impurity) can also be added.

The electronic device of the present disclosure may have a so-called three-terminal structure, or a two-terminal structure, as described above. Further, for example, a field-effect transistor (FET), specifically, a thin-film transistor (TFT), is configured by an electronic device having such a three-terminal structure, or alternatively, a light emitting element is configured by an electronic device having such a three-terminal structure. Namely, a light emitting element (an organic light emitting element, an organic light emitting transistor) in which an active layer emits light based on the application of a voltage to the control electrode and the first electrode and second electrode can be configured. In these electronic devices, the current flowing in the active layer from the first electrode to the second electrode is controlled based on the voltage applied to the control electrode. Here, in the light emitting element, the organic semiconductor material constituting the active layer has a light-emitting function based on charge storage due to modulation based on the voltage applied to the control electrode and recombination of the injected electrons and holes. Emission intensity, which is proportional to the absolute value of the current flowing from the first electrode to the second electrode, can be modulated the voltage applied to the control electrode and the voltage applied between the first electrode and the second electrode. Whether the electronic device exhibits a function as a field-effect transistor or as a light emitting element depends on the state (bias) of voltage application to the first and second electrodes. First, when the control electrode is modulated under a condition in which a bias is applied in a range where electrons are not injected from the second electrode, a current flows from the first electrode to the second electrode. This is a transistor operation. On the other hand, when the bias to the first electrode and the second electrode is increased under a condition in which holes have been sufficiently stored, electron injection starts, and light is emitted based on the recombination with holes. Further, an example of an electronic device having a two-terminal structure includes a photoelectric conversion element in which current flows between the first electrode and the second electrode by irradiation of light on the active layer. If a photoelectric conversion element is configured by the electronic device, specifically, a solar cell or various sensors, such as an image sensor or a light sensor, can be configured by the photoelectric conversion element. Alternatively, the electronic device can configure an organic electroluminescence element (organic EL element) or an organic EL display device, and can function as a chemical substance sensor. Namely, the electronic device can be used in a mode as a display element, a display device, a solar cell, or a sensor. Alternatively, it can be used as a capacitor. It is noted that the photoelectric conversion element can also be configured from an electronic device having a three-terminal structure. In this case, a voltage may or may not be applied to the control electrode. If a voltage is applied, the current that is flowing can be modulated based on the application of the voltage to the control electrode.

The first electrode and second electrode, and the active layer are formed on the base, or alternatively, above the base.

In the case of configuring a semiconductor device from the electronic device according to present disclosure, specific examples of the semiconductor device include a bottom-gate/bottom-contact type field-effect transistor (FET), a bottom-gate/top-contact type FET, a top-gate/bottom-contact type FET, and a top-gate/top-contact type FET.

If the semiconductor device is configured by a bottom-gate/bottom-contact type field-effect transistor (FET), this bottom-gate/bottom-contact type FET includes

(A) a gate electrode (control electrode) formed on a base,

(B) a gate insulating layer (insulating layer) formed on the gate electrode and the base,

(C) source/drain electrodes (first electrode and second electrode) formed on the gate insulating layer, and

(D) a channel formation region configured by an active layer, which is formed on the gate insulating layer between the source/drain electrodes.

Alternatively, if the semiconductor device is configured by a bottom-gate/top-contact type FET, this bottom-gate/top-contact type FET includes

(A) a gate electrode (control electrode) formed on a base,

(B) a gate insulating layer (insulating layer) formed on the gate electrode and the base,

(C) a channel formation region and a channel formation region extension portion which are formed on the gate insulating layer and are configured by an active layer, and

(D) source/drain electrodes (first electrode and second electrode) formed on the channel formation region extension portion.

Alternatively, if the semiconductor device is configured by a top-gate/bottom-contact type FET, this top-gate/bottom-contact type FET includes

(A) source/drain electrodes (first electrode and second electrode) formed on a base,

(B) a channel formation region which is formed on the base between the source/drain electrodes and is configured by an active layer,

(C) a gate insulating layer (insulating layer) formed on the source/drain electrodes and the channel formation region, and

(D) a gate electrode (control electrode) formed on the gate insulating layer.

Alternatively, if the semiconductor device is configured by a top-gate/top-contact type FET, this top-gate/top-contact type FET includes

(A) a channel formation region and a channel formation region extension portion which are formed on a base and are configured by an active layer,

(B) source/drain electrodes (first electrode and second electrode) formed on the channel formation region extension portion,

(C) a gate insulating layer (insulating layer) formed on the source/drain electrodes and the channel formation region, and

(D) a gate electrode (control electrode) formed on the gate insulating layer.

Here, the base can be configured by a silicon oxide-based material (e.g., SiOₓ, spin-on glass (SOG), silicon oxynitride (SiON)); silicon nitride (SiN_{Y}); a metal oxide high-dielectric insulating film, such as aluminum oxide (Al₂O₃) and HfO₂; metal oxides; and metal salts. If the base is configured by these materials, the base may be formed on a support (or above a support) appropriately selected from among the materials listed below. Namely, examples of the support, or alternatively, a base other than the above-described base, include organic polymers (in the form of a polymer material of a flexible plastic film, a plastic sheet, or a plastic substrate configured by a polymer material), such as polymethylmethacrylate (PMMA), polyvinyl alcohol (PVA), polyvinyl phenol (PVP), polyether sulfone (PES), polyimide, polycarbonate (PC), polyethylene terephthalate (PET), polyethylene naphthalate (PEN), and the like. Alternatively, examples may include natural mineral-based insulating materials, such as mica, metal-based semiconductor materials, molecular semiconductor materials and the like. If a base configured by such a flexible polymer material is used, for example, the electronic device can be mounted on or integrated with an image display device (display device) or electronic apparatus having a curved surface shape. Alternatively, further examples of the base include various glass substrates, various glass substrates in which an insulating film is formed on the surface, a quartz substrate, a quartz substrate in which an insulating film is formed on the surface, a silicon substrate in which an insulating film is formed on the surface, a conductive substrate (metals such as gold, aluminum, and stainless steel, a substrate configured by alloys, and a substrate including highly-oriented graphite) in which an insulating film is formed on the surface. As the support having an electrical insulating property, a suitable material may be selected from among the above-described materials. Further examples of the support include a conductive substrate (a substrate including a metal such as gold and aluminum, a substrate including highly-oriented graphite, a stainless steel substrate etc.). In addition, depending on the mode and structure of the electronic device, the electronic device may be disposed on a support member, and this support member may be configured by the above-described materials.

Examples of the material constituting the control electrode, first electrode, second electrode, gate electrode, source/drain electrodes, and wiring (hereafter, these are collectively referred to as “control electrode etc.”) include metals, such as platinum (Pt), gold (Au), palladium (Pd), chromium (Cr), nickel (Ni), aluminum (Al), silver (Ag), tantalum (Ta), tungsten (W), copper (Cu), titanium (Ti), indium (In), tin (Sn), iron (Fe), cobalt (Co), zinc (Zn), magnesium (Mg), manganese (Mn), ruthenium (Rh), a rubidium (Rb), and molybdenum (Mo), or, conductive substances, such as an alloy including these metals elements, conductive particles including these metals, conductive particles including an alloy of these metals, polysilicon containing impurities, a carbon material and the like. A laminated structure layers including these elements can also be used. However, it is preferred to constitute the electrode in contact with the organic semiconductor layer from, especially, copper (Cu) or aluminum (Al), as this enables good transistor properties with a low barrier to carrier injection to be realized, and is also preferred from a cost perspective. Alternatively, further examples of the material constituting the control electrode etc. include an organic material (conductive polymer), such as poly (3,4-ethylenedioxythiophene)/polystyrene sulfonate [PEDOT/PSS], TTF-TCNQ, and poly aniline. The materials which constitute the control electrode etc. may be the same material or a different material.

Although the method for forming the control electrode etc. depends on the materials constituting these parts, examples may include a physical vapor deposition method (PVD method); pulsed laser deposition (PLD), an arc discharge method; various chemical vapor deposition methods including an MOCVD method; a spin coating method; various printing methods, such as a screen printing method, an ink jet printing method, an offset printing method, a reverse offset printing method, a gravure printing method, a gravure offset printing method, relief printing, flexo printing, and a micro contact method; various coating methods, such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit coater method, a slit orifice coater method, a calender coater method, a casting method, a capillary coater method, a bar coater method, and a dipping method; a stamp method; a casting method; a method using a dispenser; a spray method; a lift-off method; a shadow mask method; as well as a combination of any plating method, such as an electrolytic plating method, an electroless plating method, or a combination thereof, with optionally a patterning technique. Examples of the PVD method include (a) an electron beam heating method, a resistance heating evaporation method, various vacuum deposition methods, such as flash evaporation, a method of heating a crucible and the like (b) a plasma evaporation method, (c) various sputtering methods, such as a diode sputtering method, a direct-current sputtering method, a direct-current magnetron sputtering method, a high-frequency sputtering method, a magnetron sputtering method, an ion beam sputtering method, a bias sputtering method and the like, and (d) various ion ion plating methods, such as a DC (direct current) method, a RF method, a multi-cathode method, an activation reaction method, a field evaporation method, a high-frequency ion plating method, a reactive ion plating method and the like. When the control electrode etc. are formed based on an etching method, a dry-etching method or a wet-etching method may be employed. Examples of dry-etching methods include ion milling and reactive ion etching (RIE). Further, the control electrode etc. may also be formed based on a laser ablation method, a mask evaporation method, a laser transfer method and the like.

Examples of the material constituting the insulating layer (the gate insulating layer) not only include an inorganic insulating material, such as a silicon oxide-based material; silicon nitride (SiN_{Y}); and a metal oxide high-dielectric insulating film, such as aluminum oxide (Al₂O₃) and HfO₂, but also an organic insulating material (organic polymer), such as a straight-chain hydrocarbon having on one end a functional group that can be bonded to the control electrode etc. (the gate electrode), such as polymethylmethacrylate (PMMA); polyvinyl phenol (PVP); polyvinyl alcohol (PVA); polyimide; polycarbonate (PC); polyethylene terephthalate (PET); polystyrene; a silanol derivative (silane coupling agent) such as N-2(aminoethyl)-3-aminopropyltrimethoxysilane (AEAPTMS), 3-mercaptopropyltrimethoxysilane (MPTMS), or octadecyltrichlorosilane (OTS); octadecanethiol; and dodecyl isocyanate). A combination of these may also be used. Here, examples of the silicon oxide-based material include oxidized silicon (SiO_{X}), BPSG, PSG, BSG, AsSG, PbSG, silicon oxynitride (SiON), SOG (spin-on glass), or a low-permittivity material (e.g., polyarylether, cycloperfluorocarbon polymer and benzocyclobutene, a cyclic fluororesin, an amorphous resin (e.g., CYTOP manufactured by Asahi Glass Co., Ltd.), polytetrafluoroethylene, fluorinated aryl ether, fluorinated polyimide, amorphous carbon, and organic SOG).

The insulating layer (gate insulating layer) can be formed by the above-described various PVD methods; various CVD methods, a spin coating method; the above-described various printing methods; the above-described various coating methods; a dipping method; a casting method; a sol-gel method; an electrodeposition method; a shadow mask method; as well as any spray method. Alternatively, the insulating layer can also be formed by oxidizing or nitriding the surface of the control electrode (gate electrode), or obtained by forming an oxide film or a nitride film on the surface of the control electrode. Although the method of oxidizing the surface of the control electrode depends on the material constituting the control electrode, examples may include an oxidizing method using O₂ plasma or an anodization method. Further, although the method of nitriding the surface of the control electrode depends on the materials constituting the control electrode, examples may include a nitriding method using N₂ plasma. Alternatively, for an Au electrode, the insulating layer (gate insulating layer) can also be formed on the surface of the control electrode (the gate electrode) by, for example, covering the control electrode surface in a self-organizing manner by a method such as a dipping method with insulating molecules having a functional group capable of forming a chemical bond with the control electrode, like a linear hydrocarbon in which one end is modified by a mercapto group. Alternatively, the insulating layer (the gate insulating layer) may be formed by modifying the surface of the control electrode (the gate electrode) with a silanol derivative (silane coupling agent).

Examples of the method for coating the mixed solution and the method for forming the organic semiconductor layer, the active layer, or the channel formation region and the channel formation region extension portion, include a spin coating method; the above-described various printing methods; the above-described various coating methods; a stamping method; a casting method; a method using a dispenser; and a wet deposition method such as a spraying method. The active layer can also optionally be patterned by a known method such as, for example, a wet etching method, a dry etching method, or a laser ablation method. A known solvent selected as appropriate may be used as the solvent in the mixed solvent. Specific examples include at least one kind selected from xylene, p-xylene, mesitylene, toluene, tetralin, anisole, benzene, 1,2-dichlorobenzene, o-dichlorobenzene, cyclohexane, and ethyl cyclohexane. The drying conditions of the mixed solution (the time, temperature etc.) can be appropriately determined based on the used solvent and the like.

Examples of devices in which the electronic device according to the present disclosure is mounted may include, for example, an image display device. Here, examples of an image display device may include a so-called desktop type personal computer, a notebook type personal computer, a mobile type personal computer, a PDA (personal digital assistant), a mobile phone, a game machine, electronic paper such as an electronic book and an electronic newspaper, a message board such as a signboard, a poster, and a blackboard, a copy machine, rewritable paper to substitute for printer paper, a calculator, a display unit in household appliances, a card display unit such as a point card, and various image display devices in electronic advertizing and electronic POP (e.g., an organic electroluminescence display device, a liquid crystal display device, a plasma display device, an electrophoretic display device, a cold cathode field emission display device etc.). Further examples include various lighting apparatuses.

If the electronic device is applied or used in various image display devices or various electronic machines, the used electronic device may be used as a monolithic integrated circuit in which multiple electronic devices have been integrated on a support member, or each electronic device may be individually separated and used as a discrete component. Further, the electronic device may be sealed with a resin.

### Working Example 1

Working Example 1 relates to the organic semiconductor layer according to the first to third embodiments of the present disclosure, the electronic device according to the present disclosure, and the method for manufacturing an electronic device according to the present disclosure.

When described based on the organic semiconductor layer according to the first embodiment of the present disclosure, the organic semiconductor layer of Working Example 1 is formed from a mixture of a first polycyclic aromatic hydrocarbon to which a substituent R₁ other than a hydrogen atom is bonded by a single bond and a second polycyclic aromatic hydrocarbon. Specifically, the first polycyclic aromatic hydrocarbon has a phenyl group and a substituent R₁ that is bonded to the phenyl group. Here, the first polycyclic aromatic hydrocarbon is, specifically, formed from 3,9-diphenyl peri-xanthenoxanthene (Ph-PXX), and as shown in the following structural formula (10) or structural formula (11), the substituent R₁ is bonded to the respective para-positions of the phenyl group. Further, the substituent R₁ is an alkyl group, specifically, an ethyl group (structural formula (10)) or a propyl group (structural formula (11)). It is noted that structural formula (10) is sometimes referred below to as “C2-Ph-PXX”, and structural formula (11) is sometimes referred to below as “C3-Ph-PXX”.

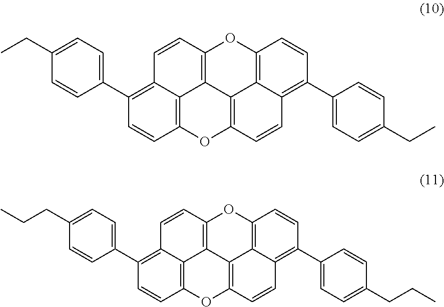

Further, the second polycyclic aromatic hydrocarbon has a phenyl group and a second substituent R₂ that is bonded to the phenyl group. Here, the first polycyclic aromatic hydrocarbon to which the substituent R₁ is bonded by a single bond and the second polycyclic aromatic hydrocarbon having a phenyl group to which the second substituent R₂ is bonded are different (structure 1 of the second polycyclic aromatic hydrocarbon).

In addition, the second polycyclic aromatic hydrocarbon is, specifically, formed from 3,9-diphenyl peri-xanthenoxanthene (Ph-PXX), and the second substituent R₂ is bonded to the respective ortho- or meta-positions of the phenyl group. The structural formula of such a second polycyclic aromatic hydrocarbon (structure 1A of the second polycyclic aromatic hydrocarbon) is shown below.

### Working Example 1a to Working Example 1f

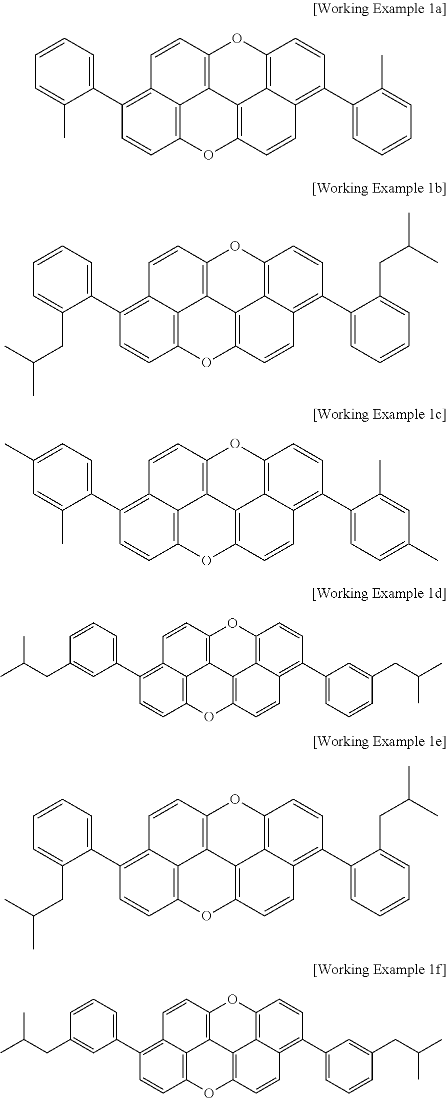

Alternatively, the second polycyclic aromatic hydrocarbon is, specifically, formed from Ph-PXX, the second substituent R₂ is bonded to the respective para-positions of the phenyl group, and the substituent R₁ and the second substituent R₂ are different. The structural formula of such a second polycyclic aromatic hydrocarbon (structure 1B of the second polycyclic aromatic hydrocarbon) is shown below.

### Working Example 1g to Working Example 1o

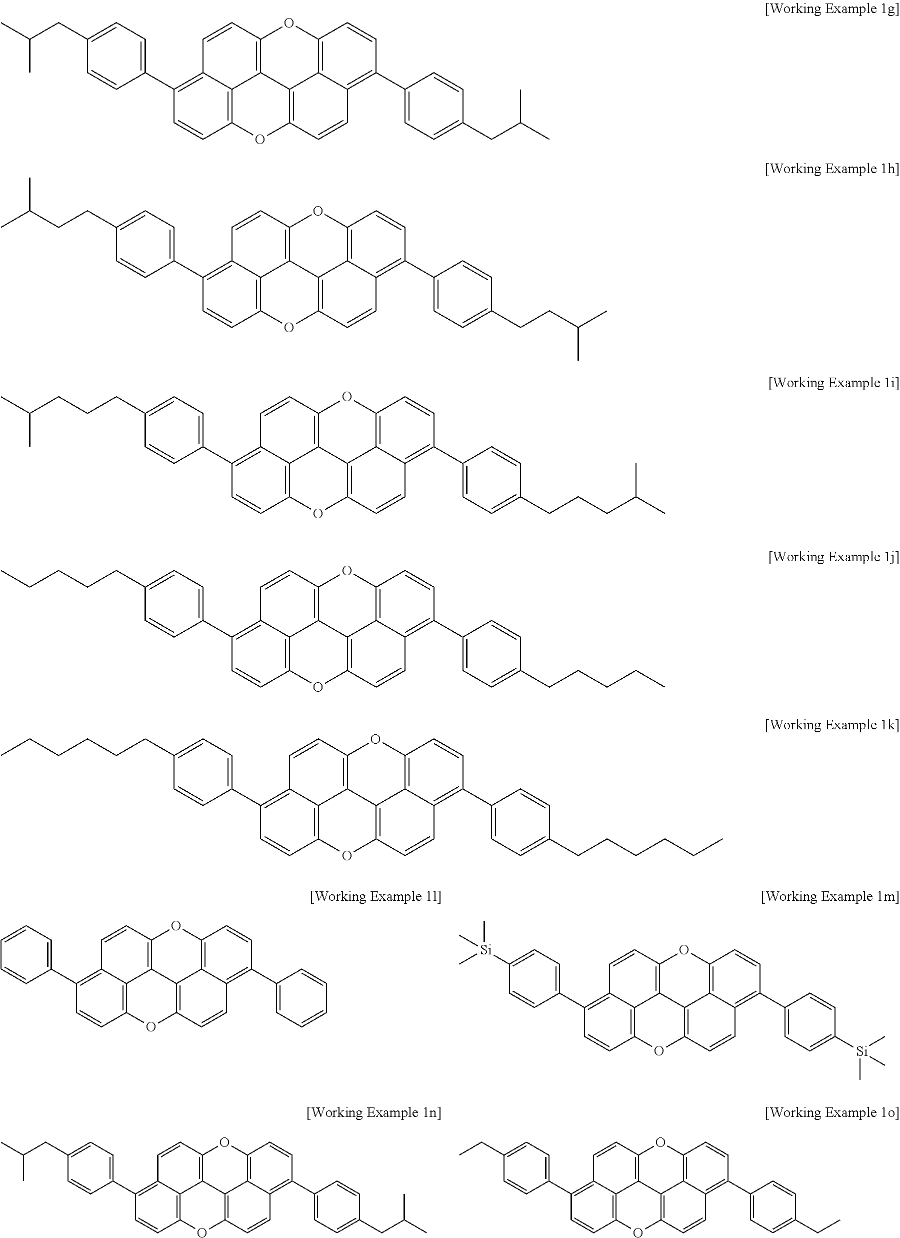

Alternatively, the second polycyclic aromatic hydrocarbon is, specifically, formed from 2,8-diphenyl peri-xanthenoxanthene or 1,7-diphenyl peri-xanthenoxanthene. The structural formula of such a second polycyclic aromatic hydrocarbon (structure 1C of the second polycyclic aromatic hydrocarbon) is shown below.

### Working Example 1p to Working Example 1r

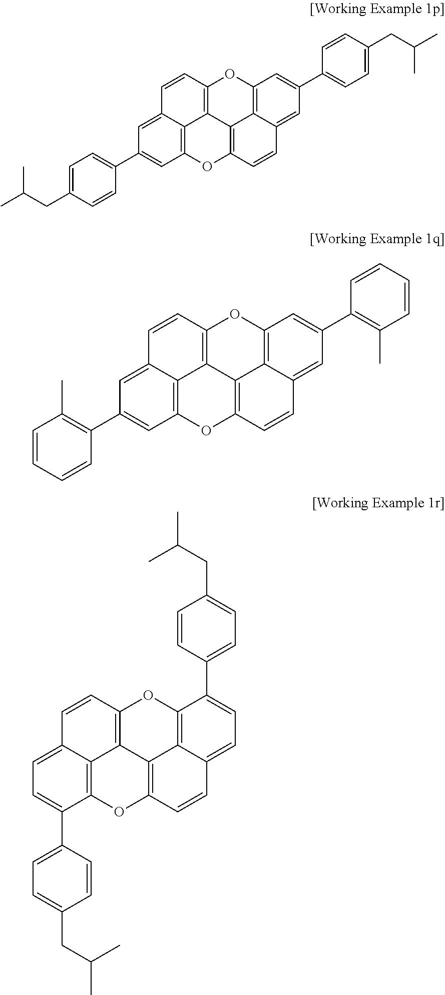 [SMILES: CC(C)Cc1ccc(-c2cc3ccc4oc5cc(-c6ccc(CC(C)C)cc6)cc6ccc7oc(c2)c3c4-c7c65)cc1 ; Cc1ccccc1-c1cc2ccc3oc4cc(-c5ccccc5C)cc5ccc6oc(c1)c2c3-c6c54 ; CC(C)Cc1ccc(-c2ccc3ccc4oc5c(-c6ccc(CC(C)C)cc6)ccc6ccc7oc2c3c4-c7c65)cc1]

Alternatively, the second polycyclic aromatic hydrocarbon is formed from TIPS-pentacene.

### Working Example 1s

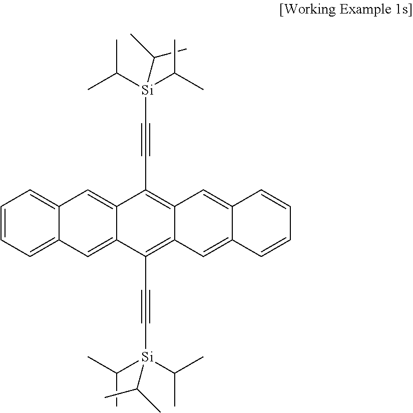 [SMILES: CC(C)[Si](C#Cc1c2cc3ccccc3cc2c(C#C[Si](C(C)C)(C(C)C)C(C)C)c2cc3ccccc3cc12)(C(C)C)C(C)C]

Alternatively, when described based on the organic semiconductor layer according to the second embodiment of the present disclosure, the organic semiconductor layer of Working Example 1 is formed from a mixture of a first polycyclic aromatic hydrocarbon to which a first substituent R₁ other than a hydrogen atom is bonded by a single bond and a second polycyclic aromatic hydrocarbon to which a second substituent R₂ other than a hydrogen atom is bonded by a single bond; the first polycyclic aromatic hydrocarbon and the second polycyclic aromatic hydrocarbon are formed from the same polycyclic aromatic hydrocarbon; and the binding site of the first substituent R₁ to the first polycyclic aromatic hydrocarbon is different to the binding site of the second substituent R₂ to the second polycyclic aromatic hydrocarbon. Further, in Working Example 1, specifically, the first polycyclic aromatic hydrocarbon and the second polycyclic aromatic hydrocarbon are formed from Ph-PXX, the binding site of the first substituent R₁ to the first polycyclic aromatic hydrocarbon is a para-position of the phenyl group constituting the first polycyclic aromatic hydrocarbon, and the binding site of the second substituent R₂ to the second polycyclic aromatic hydrocarbon is an ortho-position or a meta-position of the phenyl group constituting the second polycyclic aromatic hydrocarbon.

Specifically, the first polycyclic aromatic hydrocarbon is formed from C2-Ph-PXX or C3-Ph-PXX, and the second polycyclic aromatic hydrocarbon has a structural formula shown in Working Example 1a to Working Example 1f.

Alternatively, when described based on the organic semiconductor layer according to the third embodiment of the present disclosure, the organic semiconductor layer of Working Example 1 is formed from a mixture of a first polycyclic aromatic hydrocarbon to which a first substituent R₁ other than a hydrogen atom is bonded by a single bond and a second polycyclic aromatic hydrocarbon to which a second substituent R₂ other than a hydrogen atom is bonded by a single bond; the first polycyclic aromatic hydrocarbon and the second polycyclic aromatic hydrocarbon are formed from the same polycyclic aromatic hydrocarbon; the binding site of the first substituent R₁ to the first polycyclic aromatic hydrocarbon and the binding site of the second substituent R₂ to the second polycyclic aromatic hydrocarbon are the same; and the first substituent R₁ and the second substituent R₂ are different. Further, in Working Example 1, specifically, the first polycyclic aromatic hydrocarbon and the second polycyclic aromatic hydrocarbon are formed from Ph-PXX; the binding site of the first substituent R₁ to the first polycyclic aromatic hydrocarbon is a para-position of the phenyl group constituting the first polycyclic aromatic hydrocarbon; and the binding site of the second substituent R₂ to the second polycyclic aromatic hydrocarbon is a para-position of the phenyl group constituting the second polycyclic aromatic hydrocarbon.

Specifically, the first polycyclic aromatic hydrocarbon is formed from C2-Ph-PXX or C3-Ph-PXX, and the second polycyclic aromatic hydrocarbon has a structural formula shown in Working Example 1g to Working Example 1k or Working Example 1m to Working Example 1o.

The electronic device of Working Example 1, or the electronic device of the below-described Working Example 2 to Working Example 5, includes at least

a first electrode,

a second electrode disposed separated from the first electrode, and

an active layer provided from the first electrode to the second electrode,

wherein the active layer is formed from a mixture of a first polycyclic aromatic hydrocarbon formed from C2-Ph-PXX or C3-Ph-PXX and a second polycyclic aromatic hydrocarbon formed from the organic semiconductor layer of the above-described Working Example 1a to Working Example 1s.

Specifically, the electronic device of Working Example 1 or of the below-described Working Example 2 to Working Example 4 is a three-terminal type electronic device that includes

a first electrode,

a second electrode disposed separated from the first electrode, and

a control electrode, and

an insulating layer,

wherein the control electrode is provided facing a portion of an active layer that is positioned between the first electrode and the second electrode via the insulating layer.

More specifically, the three-terminal type electronic devices of Working Example 1 and the below Working Examples 2 to 4 are field-effect transistors (FETs) in which the current flowing in an active layer from a first electrode to a second electrode is controlled based on the voltage applied to a control electrode, in which the control electrode corresponds to a gate electrode, the first electrode and the second electrode correspond to source/drain electrodes, an insulating layer corresponds to a gate insulating layer film, and the active layer corresponds to a channel formation region.

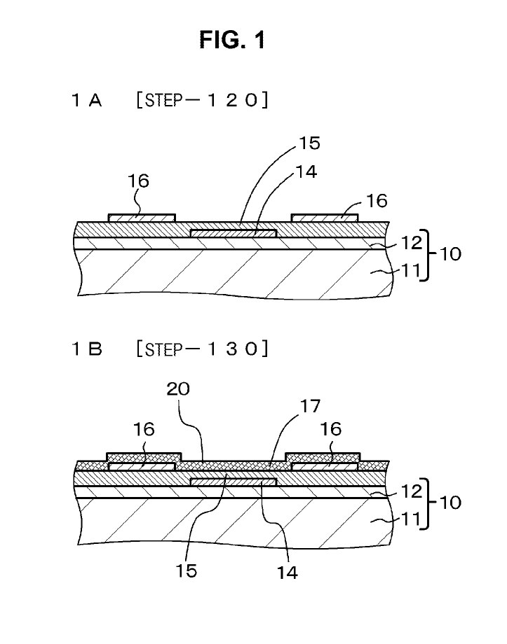

Namely, as illustrated in the schematic partial end view of FIG. 1B, the electronic device of Working Example 1 is a semiconductor device, specifically, a bottom-gate/bottom-contact type field-effect transistor (more specifically, a thin-film transistor (TFT)), which includes

(A) a gate electrode 14 (corresponding to the control electrode) formed on a base 10,

(B) a gate insulating layer 15 (corresponding to an insulating layer) formed on the gate electrode 14 and the base 10,

(C) source/drain electrodes 16 (corresponding to the first electrode and the second electrode) formed on the gate insulating layer 15, and

(D) a channel formation region 17 configured by an active layer 20, which is formed on the gate insulating layer 15 between the source/drain electrodes 16.

An outline of the method for manufacturing the electronic device (field-effect transistor) of Working Example 1 will now be described with reference to FIGS. 1A and 1B, which are schematic partial end views of the base and the like.

### Step-100

First, the gate electrode 14 is formed on the base 10. Specifically, based on a photolithography technique, a resist layer (not illustrated), from which the portion where the gate electrode 14 is to be formed has been removed, is formed on the insulating film 12 including SiO₂ that is formed on the surface of the glass substrate 11. Then, a titanium (Ti) layer (not illustrated) as an adhesion layer and a gold (Au) layer as the gate electrode 14 are successively deposited on the whole face by a vacuum deposition method, after which the resist layer is removed. In this way, based on a so-called lift-off method, the gate electrode 14 can be obtained (refer to FIG. 8A). It is noted that the gate electrode 14 can also be formed on the insulating film 12 including SiO₂ that is formed on the surface of the glass substrate 11 based on a printing method.

### Step-110

Next, the gate insulating layer 15 corresponding to the insulating layer is formed on the base 10 (more specifically, the insulating film 12 formed on the surface of the glass substrate 11) including the gate electrode 14. Specifically, the gate insulating layer 15 that includes SiO₂ is formed on the gate electrode 14 and the insulating film 12 based on a sputtering method. When depositing the gate insulating layer 15, an extraction portion (not illustrated) of the gate electrode 14 can be formed without using a photolithography process by covering a part of the gate electrode 14 with a hard mask.

### Step-120

Then, source/drain electrodes 16 formed from a 25 nm-thick copper (Cu) layer are formed on the gate insulating layer 15 based on a screen printing method (refer to FIG. 1A). Forming the source/drain electrodes 16 from copper (Cu) in this way enables properties to be improved, such as a decrease in contact resistance and an improvement in mobility.

### Step-130

Next, specifically, a mixture of the first polycyclic aromatic hydrocarbon formed from the C2-Ph-PXX or C3-Ph-PXX represented in structural formula (10) and structural formula (11) and the second polycyclic aromatic hydrocarbon described in Working Example 1a to Working Example 1s, in which the mass of the second polycyclic aromatic hydrocarbon is 0.053 based on a mass of “1” of the first polycyclic aromatic hydrocarbon, was dissolved to a mass of 0.5% by mass in a solvent, such as tetralin, xylene, toluene and the like, or a mixed solvent obtained by mixing these with a high boiling point solvent. Then, the channel formation region 17 (active layer 20) can be formed on the gate insulating layer 15 and the source/drain electrodes 16 by coating and drying the relevant mixed solution (A) or mixed solution (B) or mixed solution (C) based on a spin coating method (refer to FIG. 1B).

### Step-140

For example, in the manufacture of an image display device, following on from this step, an image display device can be manufactured by forming an image display unit (specifically, an image display unit including an organic electroluminescence element or an electrophoretic display element, a semiconductor light emitting element or the like) based on a known method on or above the thus-obtained TFT, which is an electronic device constituting the control unit (pixel drive circuit) of an image display device. Here, the thus-obtained electronic device constituting the control unit (pixel drive circuit) of an image display device and the electrodes (e.g., pixel electrodes) in the image display unit may be, for example, connected by a connection portion such as a contact hole or a wire. In the below-described Working Example 2 to Working Example 4 as well, an image display device can be obtained by carrying out a similar step after manufacture of the electronic device is completed.

Alternatively, a passivation film (not illustrated) is formed on the whole face. By doing so, a bottom-gate/bottom-contact type semiconductor device (a FET, specifically, a TFT) can be obtained. Alternatively, a passivation film (not illustrated) may be formed on the whole face after patterning the channel formation region 17 and the gate insulating layer 15. This enables the adhesive properties of the active layer 20 and the gate insulating layer 15 to be improved.

As Comparative Example 1, an electronic device was manufactured in which the active layer was formed only from the C2-Ph-PXX represented by structural formula (10). Then, the carrier mobility of the thus-obtained electronic devices was measured. The results are shown in the following Table 1.

TABLE 1

| Working | First Polycyclic Aromatic | |
|---|---|---|
| Example | Hydrocarbon | Mobility (cm²/Vs) |
| 1a | C2-Ph-PXX | 2.5 |
| 1b | C2-Ph-PXX | 2.3 |
| 1c | C2-Ph-PXX | 2.6 |
| 1d | C2-Ph-PXX | 2.5 |
| 1e | C3-Ph-PXX | 2.6 |
| 1f | C3-Ph-PXX | 1.7 |
| 1g | C2-Ph-PXX | 2.7 |
| 1h | C2-Ph-PXX | 2.3 |
| 1i | C2-Ph-PXX | 2.0 |
| 1j | C2-Ph-PXX | 2.2 |
| 1k | C2-Ph-PXX | 2.4 |
| 1l | C2-Ph-PXX | 2.2 |
| 1m | C2-Ph-PXX | 2.4 |
| 1n | C3-Ph-PXX | 2.4 |
| 1o | C3-Ph-PXX | 3.0 |
| 1p | C2-Ph-PXX | 2.4 |
| 1q | C2-Ph-PXX | 2.6 |
| 1r | C2-Ph-PXX | 2.1 |
| 1p | C3-Ph-PXX | 1.9 |
| 1s | C2-Ph-PXX | 1.4 |
| Comparative | | 0.9~1.0 |
| Example 1 | | |

For the electronic device of Working Example 1, a mixture of two types of polycyclic aromatic hydrocarbon was used for the channel formation region, which enabled improved carrier mobility compared with Comparative Example 1. Specifically, based on a carrier mobility of “1” when the active layer is formed only from the first polycyclic aromatic hydrocarbon, excluding Working Example 1s, the carrier mobility of Working Example 1 to Working Example 1r was 2 or more.

Further, the results obtained by measuring the lattice constant and the like (a, b, c, γ) of the organic semiconductor layers obtained in Working Example 1g and Comparative Example 1 are shown in Table 2. However, no large difference can be found between Working Example 1g and Comparative Example 1.

TABLE 2

| | |
|---|---|
| Working Example 1g | Comparative Example 1 |

| | | | | |
|---|---|---|---|---|
| a | 11.57 | Å | 11.52 | Å |
| b | 12.92 | Å | 12.82 | Å |
| c | 22.2 | Å | 22.6 | Å |
| γ | 96.2 | Å | 95.7 | Å |

On the other hand, carrier mobility μ is represented by the following equation. In this equation, μ₀ represents the prefactor, Eₐ represents the activation energy, k_{B} represents the Boltzmann constant, and T represents the temperature.

μ=μ₀e×p(Eₐ/k_{B}T)

In the above equation, if the temperature is constant, then the variable parameters are μ₀ and Eₐ. Although μ₀ is a parameter that largely depends on the molecular arrangement, as shown in Table 2, since the variation in the lattice constant and the like of a thin film is small, it is thought that there is no great difference in μ₀ values between the first polycyclic aromatic hydrocarbon only (Comparative Example 1) and a mixture of the first polycyclic aromatic hydrocarbon and the second polycyclic aromatic hydrocarbon (Working Example 1g). Therefore, it is considered that the mobility μ will be improved by decreasing the value of the activation energy Eₐ. Here, one cause for the value of Eₐ decreasing is thought to be the wide domain of the thin film, namely, the increase in the crystallite size. It is widely known that crystallite size can be determined from the half-value width obtained by XRD analysis (in-plane) of the thin film. Compared with Comparative Example 1, in Working Example 1g that was obtained by mixing the first polycyclic aromatic hydrocarbon and the second polycyclic aromatic hydrocarbon, it could be confirmed that crystallite size increased, whereby it is thought that the improvement in carrier mobility was achieved. It is noted that crystallite size, which was 80 nm in Comparative Example 1, increased in Working Example g to 105 nm. Namely, the crystallite size was about 1.3 times as large.

Further, although the first polycyclic aromatic hydrocarbon and the second polycyclic aromatic hydrocarbon are dissolved in a solvent, for example, if the solubility of the first polycyclic aromatic hydrocarbon in the solvent is low, a second polycyclic aromatic hydrocarbon that has a high solubility in the solvent may be selected. By thus improving the solubility of the overall mixture of the first polycyclic aromatic hydrocarbon and the second polycyclic aromatic hydrocarbon with a high degree of selection freedom, the optimum mixed solution state when forming the organic semiconductor layer based on a coating method can be easily obtained. In addition, when forming a film by mixing two types of organic semiconductor material that have very different structures (an organic semiconductor material having a low molecular weight and an organic semiconductor material having a high molecular weight), since a molecular arrangement is formed that is completely different from the state of a thin film formed from each of the single components, there can be the problem that the film-forming conditions substantially change. When a low-molecular-weight organic semiconductor material and a high-molecular-weight organic semiconductor material are mixed, the obtained organic semiconductor layer is in an amorphous state, which can cause the problem that the off current increases. However, except for Working Example 1s, in the working examples, since two types of polycyclic aromatic hydrocarbon having the same central skeleton (the portion through which the carriers flow, which in Working Example 1 is PXX) are mixed, a molecular arrangement can be formed that is similar to the state of a thin film formed from each of the single components of the first polycyclic aromatic hydrocarbon and the second polycyclic aromatic hydrocarbon, so that there is no large change to the film-forming conditions, and the obtained organic semiconductor layer has high crystallinity. Accordingly, the problem of an increase in the off current does not occur. Namely, if a much higher concentration is required in a printing method and the like, and if the first polycyclic aromatic hydrocarbon has low solubility so that no more can be added, by adding a second polycyclic aromatic hydrocarbon that has far better solubility, the concentration can be freely adjusted.

### Working Example 2

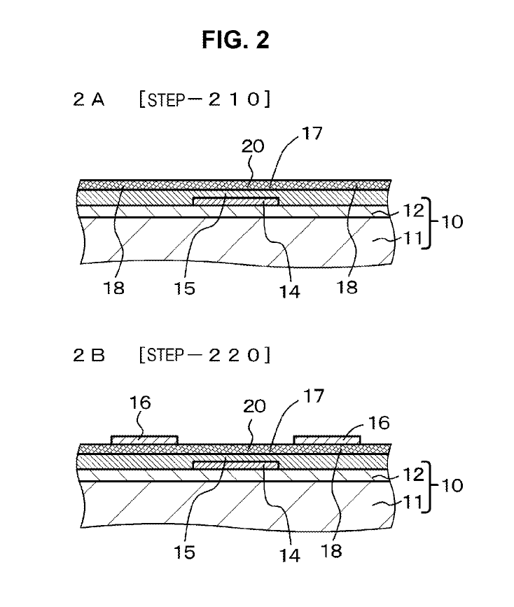

Working Example 2 is a modification of Working Example 1. In Working Example 2, the three-terminal type electronic device is a bottom-gate/top-contact type FET (specifically, a TFT). As illustrated in the schematic partial end view of FIG. 2B, the field-effect transistor of Working Example 2 includes

(A) the gate electrode 14 (corresponding to the control electrode) formed on the base 10,

(B) the gate insulating layer 15 (corresponding to an insulating layer) formed on the gate insulating layer 15 and the base 10,

(C) the channel formation region 17 and the channel formation region extension portion 18 which are formed on the gate insulating layer 15 and are configured by the active layer 20, and

(D) source/drain electrodes 16 (corresponding to the first electrode and the second electrode) formed on the channel formation region extension portion 18.

An outline of the method for manufacturing the electronic device (field-effect transistor) of Working Example 2 will now be described with reference to FIGS. 2A and 2B, which are schematic partial end views of the base and the like.

### Step-200

First, the gate electrode 14 is formed on the base 10 in the same manner as in “Step-100” of Working Example 1, and then the gate insulating layer 15 is formed on the base (more specifically, the insulating film 12) including the gate electrode 14 in the same manner as in “Step-110” of Working Example 1.

### Step-210

Next, the active layer 20 is formed on the gate insulating layer 15 in the same manner as in “Step-130” of Working Example 1 (refer to FIG. 2A). In this way, the channel formation region 17 and the channel formation region extension portion 18 can be obtained.

### Step-220

Then, the source/drain electrodes 16 are formed on the channel formation region extension portion 18 so as to sandwich the channel formation region 17 (refer to FIG. 2B). Specifically, a copper (Cu) layer as the source/drain electrodes 16 is formed based on a screen printing method in the same manner as “Step-120” of Working Example 1.

### Step-230

Next, the electronic device of Working Example 2 can be completed by carrying out the same step as in Step-140 of Working Example 1.

### Working Example 3

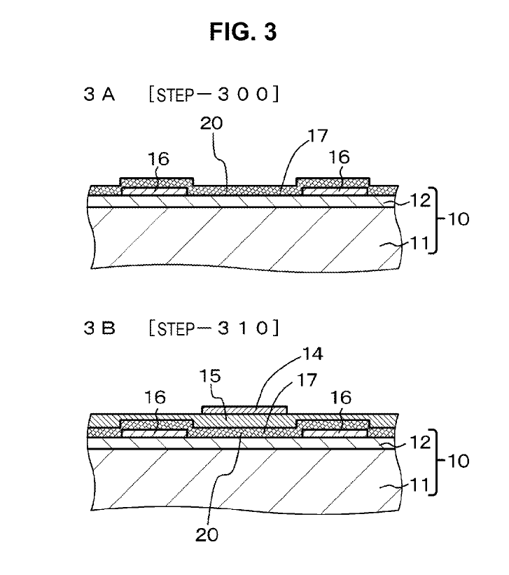

Working Example 3 is a modification of Working Example 1. In Working Example 3, the three-terminal type electronic device is a top-gate/bottom-contact type FET (specifically, a TFT). As illustrated in the schematic partial end view of FIG. 3B, the field-effect transistor of Working Example 3 includes

(A) source/drain electrodes 16 (corresponding to the first electrode and the second electrode) formed on the base 10,

(B) the channel formation region 17 which is formed on the base 10 between the source/drain electrodes 16 and is configured by the active layer 20,

(C) the gate insulating layer 15 (corresponding to the insulating layer) formed on the source/drain electrodes 16 and the channel formation region 17, and

(D) the gate electrode 14 (corresponding to the control electrode) formed on the gate insulating layer 15.

An outline of the method for manufacturing the electronic device (field-effect transistor) of Working Example 3 will now be described with reference to FIGS. 3A and 3B, which are schematic partial end views of the base and the like.

### Step-300

First, the source/drain electrodes 16 are formed on the insulating film 12 corresponding to the base in the same manner as in “Step-120” of Working Example 1, and then the channel formation region 17 (the active layer 20) is formed on the insulating film 12 including the source/drain electrodes 16 in the same manner as in “Step-130” of Working Example 1 (refer to FIG. 3A).

### Step-310

Next, the gate insulating layer 15 is formed in the same manner as in “Step-110” of Working Example 1. Then, the gate electrode 14 is formed on the portion of the gate insulating layer 15 on the channel formation region 17 in the same manner as in “Step-100” of Working Example 1 (refer to FIG. 3B).

### Step-320

Subsequently, the electronic device of Working Example 3 can be completed by carrying out the same step as in Step-140 of Working Example 1.

### Working Example 4

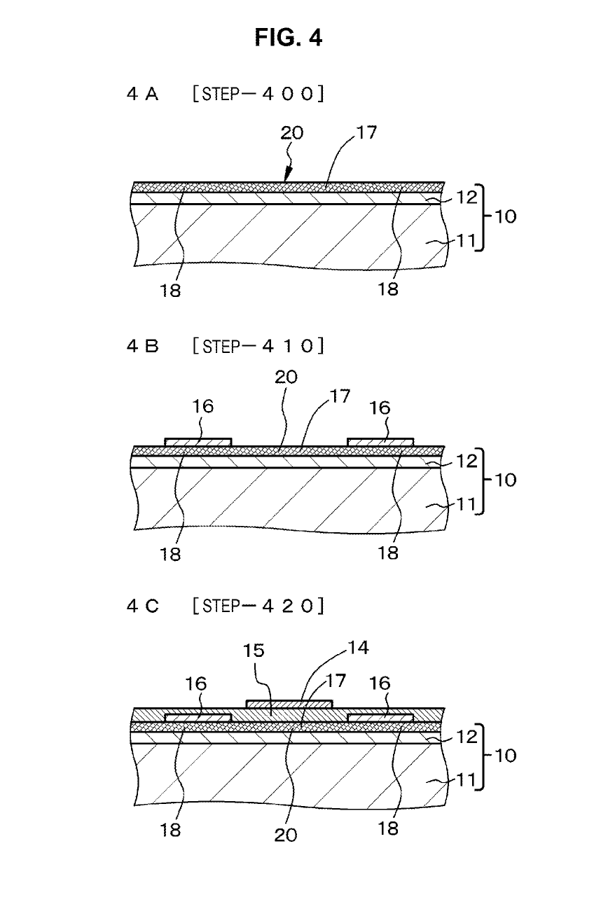

Working Example 4 is a modification of Working Example 1. In Working Example 4, the three-terminal type electronic device is a top-gate/top-contact type FET (specifically, a TFT). As illustrated in the schematic partial end view of FIG. 4C, the field-effect transistor of Working Example 4 includes

(A) the channel formation region 17 and the channel formation region extension portion 18 formed on the base 10 and configured by the active layer 20,

(B) source/drain electrodes 16 (corresponding to the first electrode and the second electrode) formed on the channel formation region extension portion 18,

(C) the gate insulating layer 15 (corresponding to the insulating layer) formed on the source/drain electrodes 16 and the channel formation region 17, and

(D) the gate electrode 14 (corresponding to the control electrode) formed on the gate insulating layer 15.

An outline of the method for manufacturing the electronic device (field-effect transistor) of Working Example 4 will now be described with reference to FIGS. 4A, 4B, and 4C, which are schematic partial end views of the base and the like.

### Step-400

First, the channel formation region 17 and the channel formation region extension portion 18 can be obtained by forming the active layer 20 on the base 10 (more specifically, the insulating film 12) in the same manner as in “Step-130” of Working Example 1 (refer to FIG. 4A).

### Step-410

Next, the source/drain electrodes 16 are formed on the channel formation region extension portion 18 in the same manner as in “Step-120” of Working Example 1 (refer to FIG. 4B).

### Step-420

Then, the gate insulating layer 15 is formed in the same manner as in “Step-110” of Working Example 1. Next, the gate electrode 14 is formed on the portion of the gate insulating layer 15 on the channel formation region 17 in the same manner as in “Step-100” of Working Example 1 (refer to FIG. 4C).

### Step-430

Next, the electronic device of Working Example 4 can be completed by carrying out the same step as in Step-140 of Working Example 1.

### Working Example 5

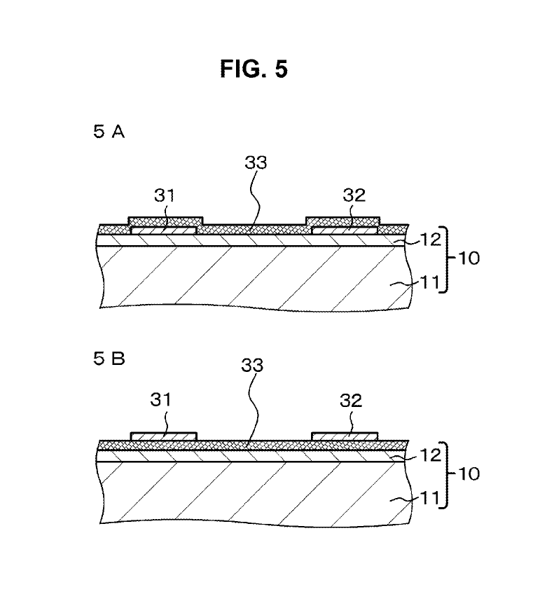

Although Working Example 5 is also a modification of Working Example 1, in Working Example 5 the electronic device is specifically a two-terminal type electronic device, and more specifically, as illustrated in the schematic partial end views of FIG. 5A or 5B, includes

a first electrode 31 and a second electrode 32, and

an active layer 33 formed between the first electrode 31 and the second electrode 32.

It is noted that the active layer 33 is formed from a mixture of the first polycyclic aromatic hydrocarbon formed from C2-Ph-PXX or C3-Ph-PXX and the second polycyclic aromatic hydrocarbon formed from described in Working Examples 1a to 1s. Further, power is generated by the irradiation of light on the active layer 33. Namely, the electronic device of Working Example 5 functions as a photoelectric conversion element or a solar cell. Alternatively, the electronic device of Working Example 8 functions as a light emitting element in which the active layer 33 emits light due to the application of a voltage to the first electrode 31 and the second electrode 32.

Alternatively, the electronic device of Working Example 5 can also function as a chemical substance sensor including a two-terminal type electronic device. Specifically, when a chemical substance to be detected is adsorbed on the active layer 33, the electric resistance value between the first electrode 31 and the second electrode 32 changes. Therefore, the amount (concentration) of the chemical substance adsorbed on the active layer 33 can be measured by flowing a current between the first electrode 31 and the second electrode 32, or alternatively, applying an appropriate voltage between the first electrode 31 and the second electrode 32, and measuring the electric resistance value of the active layer 33. It is noted that since the chemical substance is in an adsorption equilibrium state at the active layer 33, if the amount (concentration) of the chemical substance in the atmosphere in which the active layer 33 is placed changes, the equilibrium state also changes.

Excluding the above points, basically, the composition and structure of the electronic device of Working Example 5 may be essentially the same as the composition and structure of the electronic device described in Working Example 1 or 2, apart from the point that a control electrode and an insulating layer are not provided. Accordingly, a detailed description thereof will be omitted. The electronic device of Working Example 5 can be obtained by executing the same steps as “Step-120” to “Step-130” of Working Example 1, or alternatively, by executing the same steps as “Step-210” to “Step-220” of Working Example 2.

Although the present disclosure was described above based on preferred working examples, the present disclosure is not limited to these working examples. The specific structure of the first polycyclic aromatic hydrocarbon and the second polycyclic aromatic hydrocarbon is not limited to the working examples. Further, the structure, configuration, formation conditions, or manufacturing conditions of the electronic device are examples that can be appropriately changed. In some cases, a plurality of types of the first polycyclic aromatic hydrocarbon and one type of the second polycyclic aromatic hydrocarbon may be mixed, one type of the first polycyclic aromatic hydrocarbon and a plurality of types of the second polycyclic aromatic hydrocarbon may be mixed, or a plurality of types of the first polycyclic aromatic hydrocarbon and a plurality of types of the second polycyclic aromatic hydrocarbon may be mixed. If the electronic device according to the present disclosure is applied or used in, for example, various image display devices or electronic apparatus, multiple electronic devices may be integrated on a support member to form a monolithic integrated circuit, or individual electronic devices may be separated and used as discrete parts.

For example, in the method for manufacturing the bottom-gate/top-contact type FET (specifically, a TFT) of Working Example 2, the gate insulating layer 15 and the active layer 20 (the channel formation region 17 and the channel formation region extension portion 18) can also be formed based on the below-described phase separation method. Namely, a mixed solution is prepared by uniformly dissolving the first polycyclic aromatic hydrocarbon, the second polycyclic aromatic hydrocarbon, and poly(α-methylstyrene), which is an organic insulating material. Further, a first gate insulating layer that covers the base 10 and the gate electrode 14 is formed in a step similar to “Step-200” of Working Example 2. Specifically, a first gate electrode layer formed from polyvinyl phenol can be obtained by coating a polyvinyl phenol (PVP) solution including an insulating material formed from a photocurable or thermosetting organic material (polymer) and, for example, a cross-linking agent based on a spin coating method on the base 10 and the gate electrode 14, and then heating to 150° C. Next, the above-described mixed solution is coated on the first gate electrode layer based on a spin coating method, and then the obtained coated film is dried in an air atmosphere at 100° C. or more, and preferably 130° C. or more, for 20 to 30 minutes. Consequently, phase separation spontaneously occurs in the coated film, so that a laminated structure of a second gate insulating layer formed from poly(α-methylstyrene) and an organic semiconductor layer above that layer is formed. Then, the same steps as in “Step-220” and “Step-230” of Working Example 2 can be carried out. Thus, since there is no contamination of the second gate insulating layer before the organic semiconductor layer is formed, the interface between the second gate insulating layer and the organic semiconductor layer has a high degree of smoothness, and these layers have a high degree of film thickness precision, an electronic device can be manufactured that has little unevenness in its properties and excellent performance. It is noted that the above-described method for manufacturing an electronic device, or, method for manufacturing an electronic device that is described below, can also be applied to Working Example 3 and Working Example 4.

Alternatively, a cyclic cycloolefin polymer or cyclic cycloolefin copolymer, specifically, for example, TOPAS, can also be used as the organic insulating material. In this case, the mixed solution may be prepared by uniformly dissolving the first polycyclic aromatic hydrocarbon, the second polycyclic aromatic hydrocarbon, and TOPAS, which is an organic insulating material. Further, a first gate insulating layer that covers the base 10 and the gate electrode 14 is formed in a step similar to “Step-200” of Working Example 2. Specifically, a first gate electrode layer formed from polyvinyl phenol can be obtained by coating a polyvinyl phenol (PVP) solution including an insulating material formed from a photocurable or thermosetting organic material (polymer) and, for example, a cross-linking agent based on a spin coating method on the base 10 and the gate electrode 14, and then heating to 150° C. Next, the above-described mixed solution is coated on the first gate electrode layer based on a spin coating method, and then the obtained coated film is dried in an air atmosphere at 100° C. or more, and preferably 130° C. or more, for 20 to 30 minutes. Consequently, phase separation spontaneously occurs in the coated film, so that a laminated structure of a second gate insulating layer formed from TOPAS and an organic semiconductor layer above that layer is formed. Then, the same steps as in “Step-220” and “Step-230” of Working Example 2 can be carried out.

Additionally, the present disclosure may also be configured as below.

### [1] <<Organic Semiconductor Layer: First Embodiment>>

An organic semiconductor layer including:

a mixture of a first polycyclic aromatic hydrocarbon to which a substituent R₁ other than a hydrogen atom is bonded by a single bond, and a second polycyclic aromatic hydrocarbon.

[2]

The organic semiconductor layer according to [1],

wherein the first polycyclic aromatic hydrocarbon has a phenyl group, and

wherein the substituent R₁ is bonded to the phenyl group.

[3]

The organic semiconductor layer according to [2], wherein the first polycyclic aromatic hydrocarbon is formed from 3,9-diphenyl peri-xanthenoxanthene.

[4]

The organic semiconductor layer according to [3], wherein the substituent R₁ is bonded to respective para-positions of the phenyl group.

[5]

The organic semiconductor layer according to any one of [1] to [4], wherein the substituent R₁ is one kind of substituent selected from the group consisting of an alkyl group, a cycloalkyl group, an alkenyl group, an alkynyl group, an aryl group, an arylalkyl group, an aromatic heterocycle, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amide group, a carbamoyl group, a ureido group, a sulfinyl group, an alkylsulfonyl group, an arylsulfonyl group, an amino group, a halogen atom, a fluorinated hydrocarbon group, a cyano group, a nitro group, a hydroxy group, a mercapto group, and a silyl group.

[6]

The organic semiconductor layer according to any one of [1] to [5],

wherein the second polycyclic aromatic hydrocarbon has a phenyl group and a second substituent R₂ that is bonded to the phenyl group, and

wherein the first polycyclic aromatic hydrocarbon to which the substituent R₁ is bonded by a single bond and the second polycyclic aromatic hydrocarbon having the phenyl group to which the second substituent R₂ is bonded are different.

[7]

The organic semiconductor layer according to [6],

wherein the second polycyclic aromatic hydrocarbon is formed from 3,9-diphenyl peri-xanthenoxanthene, and

wherein the second substituent R₂ is bonded to respective ortho-positions or meta-positions of the phenyl group.

[8]

The organic semiconductor layer according to [6],

wherein the second polycyclic aromatic hydrocarbon is formed from 3,9-diphenyl peri-xanthenoxanthene,

wherein the second substituent R₂ is bonded to respective para-positions of the phenyl group, and

wherein the substituent R₁ and the second substituent R₂ are different.

[9]

The organic semiconductor layer according to [6], wherein the second polycyclic aromatic hydrocarbon is formed from 2,8-diphenyl peri-xanthenoxanthene or 1,7-diphenyl peri-xanthenoxanthene.

[10]

The organic semiconductor layer according to any one of [6] to [9], wherein the second substituent R₂ is one kind of substituent selected from the group consisting of a hydrogen atom, an alkyl group, a cycloalkyl group, an alkenyl group, an alkynyl group, an aryl group, an arylalkyl group, an aromatic heterocycle, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amide group, a carbamoyl group, a ureido group, a sulfinyl group, an alkylsulfonyl group, an arylsulfonyl group, an amino group, a halogen atom, a fluorinated hydrocarbon group, a cyano group, a nitro group, a hydroxy group, a mercapto group, and a silyl group.

[11]

The organic semiconductor layer according to any one of [1] to [5], wherein the second polycyclic aromatic hydrocarbon is formed from TIPS-pentacene.

### [12] <<Organic Semiconductor Layer: Second Embodiment>>

An organic semiconductor layer including:

a mixture of a first polycyclic aromatic hydrocarbon to which a first substituent R₁ other than a hydrogen atom is bonded by a single bond, and a second polycyclic aromatic hydrocarbon to which a second substituent R₂ other than a hydrogen atom is bonded by a single bond,

wherein the first polycyclic aromatic hydrocarbon and the second polycyclic aromatic hydrocarbon are formed from the same polycyclic aromatic hydrocarbon, and

wherein a binding site of the first substituent R₁ to the first polycyclic aromatic hydrocarbon is different to a binding site of the second substituent R₂ to the second polycyclic aromatic hydrocarbon.

[13]

The organic semiconductor layer according to [12],

wherein the first polycyclic aromatic hydrocarbon and the second polycyclic aromatic hydrocarbon are formed from 3,9-diphenyl peri-xanthenoxanthene,

wherein the binding site of the first substituent R₁ to the first polycyclic aromatic hydrocarbon is a para-position of a phenyl group constituting the first polycyclic aromatic hydrocarbon, and

wherein the binding site of the second substituent R₂ to the second polycyclic aromatic hydrocarbon is an ortho-position or a meta-position of a phenyl group constituting the second polycyclic aromatic hydrocarbon.

### [14] <<Organic Semiconductor Layer: Third Embodiment>>

An organic semiconductor layer including:

a mixture of a first polycyclic aromatic hydrocarbon to which a first substituent R₁ other than a hydrogen atom is bonded by a single bond, and a second polycyclic aromatic hydrocarbon to which a second substituent R₂ other than a hydrogen atom is bonded by a single bond,

wherein the first polycyclic aromatic hydrocarbon and the second polycyclic aromatic hydrocarbon are formed from the same polycyclic aromatic hydrocarbon,

wherein a binding site of the first substituent R₁ to the first polycyclic aromatic hydrocarbon is the same as a binding site of the second substituent R₂ to the second polycyclic aromatic hydrocarbon, and

wherein the first substituent R₁ and the second substituent R₂ are different.

[15]

The organic semiconductor layer according to [14],

wherein the first polycyclic aromatic hydrocarbon and the second polycyclic aromatic hydrocarbon are formed from 3,9-diphenyl peri-xanthenoxanthene,

wherein the binding site of the first substituent R₁ to the first polycyclic aromatic hydrocarbon is a para-position of a phenyl group constituting the first polycyclic aromatic hydrocarbon, and

wherein the binding site of the second substituent R₂ to the second polycyclic aromatic hydrocarbon is a para-position of a phenyl group constituting the second polycyclic aromatic hydrocarbon.

[16]

The organic semiconductor layer according to any one of [12] to [15],

wherein the first substituent R₁ is one kind of substituent selected from the group consisting of an alkyl group, a cycloalkyl group, an alkenyl group, an alkynyl group, an aryl group, an arylalkyl group, an aromatic heterocycle, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amide group, a carbamoyl group, a ureido group, a sulfinyl group, an alkylsulfonyl group, an arylsulfonyl group, an amino group, a halogen atom, a fluorinated hydrocarbon group, a cyano group, a nitro group, a hydroxy group, a mercapto group, and a silyl group, and

wherein the second substituent R₂ is one kind of substituent selected from the group consisting of a hydrogen atom, an alkyl group, a cycloalkyl group, an alkenyl group, an alkynyl group, an aryl group, an arylalkyl group, an aromatic heterocycle, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amide group, a carbamoyl group, a ureido group, a sulfinyl group, an alkylsulfonyl group, an arylsulfonyl group, an amino group, a halogen atom, a fluorinated hydrocarbon group, a cyano group, a nitro group, a hydroxy group, a mercapto group, and a silyl group.

### [17] <<Electronic Device>>

An electronic device including at least:

a first electrode;

a second electrode disposed separately from the first electrode; and

an active layer provided from the first electrode to the second electrode,

wherein the active layer is formed from the organic semiconductor layer according to any one of any one of [1] to [16].

[18]

The electronic device according to [17], including:

a first electrode;

a second electrode disposed separately from the first electrode;

a control electrode; and

an insulating layer,

wherein the control electrode is provided facing a portion of an active layer that is positioned between the first electrode and the second electrode via the insulating layer.

### [19] <<Method for Manufacturing Electronic Device>>

A method for manufacturing an electronic device, the electronic device including at least

a first electrode,

a second electrode disposed separately from the first electrode, and

an active layer provided from the first electrode to the second electrode,

the method including:

forming the active layer by coating and drying

a mixed solution formed from a mixture of a first polycyclic aromatic hydrocarbon to which a substituent R₁ other than a hydrogen atom is bonded by a single bond and a second polycyclic aromatic hydrocarbon, or

a mixed solution formed from a mixture of a first polycyclic aromatic hydrocarbon to which a first substituent R₁ other than a hydrogen atom is bonded by a single bond and a second polycyclic aromatic hydrocarbon to which a second substituent R₂ other than a hydrogen atom is bonded by a single bond,

wherein the first polycyclic aromatic hydrocarbon and the second polycyclic aromatic hydrocarbon are formed from the same polycyclic aromatic hydrocarbon, and

wherein a binding site of the first substituent R₁ to the first polycyclic aromatic hydrocarbon is different to a binding site of the second substituent R₂ to the second polycyclic aromatic hydrocarbon, or

a mixed solution formed from a mixture of a first polycyclic aromatic hydrocarbon to which a first substituent R₁ other than a hydrogen atom is bonded by a single bond and a second polycyclic aromatic hydrocarbon to which a second substituent R₂ other than a hydrogen atom is bonded by a single bond,

wherein the first polycyclic aromatic hydrocarbon and the second polycyclic aromatic hydrocarbon are formed from the same polycyclic aromatic hydrocarbon,

wherein a binding site of the first substituent R₁ to the first polycyclic aromatic hydrocarbon is the same as a binding site of the second substituent R₂ to the second polycyclic aromatic hydrocarbon, and

wherein the first substituent R₁ and the second substituent R₂ are different.

The method for manufacturing an electronic device according to claim 19, wherein an organic insulating material is further mixed in the mixed solution.

### REFERENCE SIGNS LIST

10 base
11 glass substrate
12 insulating film
14 gate electrode (control electrode)
15 gate insulating layer (insulating layer)
14 source/drain electrodes (first electrode and second electrode)
17 channel formation region
18 channel formation region extension portion
20, 33 active layer
31 first electrode
32 second electrode

1. An organic semiconductor layer comprising:
a mixture of a first polycyclic aromatic hydrocarbon to which a substituent R₁ other than a hydrogen atom is bonded by a single bond, and a second polycyclic aromatic hydrocarbon.

2. The organic semiconductor layer according to claim 1,
wherein the first polycyclic aromatic hydrocarbon has a phenyl group, and
wherein the substituent R₁ is bonded to the phenyl group.

3. The organic semiconductor layer according to claim 2, wherein the first polycyclic aromatic hydrocarbon is formed from 3,9-diphenyl peri-xanthenoxanthene.

4. The organic semiconductor layer according to claim 3, wherein the substituent R₁ is bonded to respective para-positions of the phenyl group.

5. The organic semiconductor layer according to claim 1, wherein the substituent R₁ is one kind of substituent selected from the group consisting of an alkyl group, a cycloalkyl group, an alkenyl group, an alkynyl group, an aryl group, an arylalkyl group, an aromatic heterocycle, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amide group, a carbamoyl group, a ureido group, a sulfinyl group, an alkylsulfonyl group, an arylsulfonyl group, an amino group, a halogen atom, a fluorinated hydrocarbon group, a cyano group, a nitro group, a hydroxy group, a mercapto group, and a silyl group.

6. The organic semiconductor layer according to claim 1,
wherein the second polycyclic aromatic hydrocarbon has a phenyl group and a second substituent R₂ that is bonded to the phenyl group, and
wherein the first polycyclic aromatic hydrocarbon to which the substituent R₁ is bonded by a single bond and the second polycyclic aromatic hydrocarbon having the phenyl group to which the second substituent R₂ is bonded are different.

7. The organic semiconductor layer according to claim 6,
wherein the second polycyclic aromatic hydrocarbon is formed from 3,9-diphenyl peri-xanthenoxanthene, and
wherein the second substituent R₂ is bonded to respective ortho-positions or meta-positions of the phenyl group.

8. The organic semiconductor layer according to claim 6,
wherein the second polycyclic aromatic hydrocarbon is formed from 3,9-diphenyl peri-xanthenoxanthene,
wherein the second substituent R₂ is bonded to respective para-positions of the phenyl group, and
wherein the substituent R₁ and the second substituent R₂ are different.

9. The organic semiconductor layer according to claim 6, wherein the second polycyclic aromatic hydrocarbon is formed from 2,8-diphenyl peri-xanthenoxanthene or 1,7-diphenyl peri-xanthenoxanthene.

10. The organic semiconductor layer according to claim 6, wherein the second substituent R₂ is one kind of substituent selected from the group consisting of a hydrogen atom, an alkyl group, a cycloalkyl group, an alkenyl group, an alkynyl group, an aryl group, an arylalkyl group, an aromatic heterocycle, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amide group, a carbamoyl group, a ureido group, a sulfinyl group, an alkylsulfonyl group, an arylsulfonyl group, an amino group, a halogen atom, a fluorinated hydrocarbon group, a cyano group, a nitro group, a hydroxy group, a mercapto group, and a silyl group.

11. The organic semiconductor layer according to claim 1, wherein the second polycyclic aromatic hydrocarbon is formed from TIPS-pentacene.

12. An organic semiconductor layer comprising:
a mixture of a first polycyclic aromatic hydrocarbon to which a first substituent R₁ other than a hydrogen atom is bonded by a single bond, and a second polycyclic aromatic hydrocarbon to which a second substituent R₂ other than a hydrogen atom is bonded by a single bond,
wherein the first polycyclic aromatic hydrocarbon and the second polycyclic aromatic hydrocarbon are formed from the same polycyclic aromatic hydrocarbon, and
wherein a binding site of the first substituent R₁ to the first polycyclic aromatic hydrocarbon is different to a binding site of the second substituent R₂ to the second polycyclic aromatic hydrocarbon.

13. The organic semiconductor layer according to claim 12,
wherein the first polycyclic aromatic hydrocarbon and the second polycyclic aromatic hydrocarbon are formed from 3,9-diphenyl peri-xanthenoxanthene,
wherein the binding site of the first substituent R₁ to the first polycyclic aromatic hydrocarbon is a para-position of a phenyl group constituting the first polycyclic aromatic hydrocarbon, and
wherein the binding site of the second substituent R₂ to the second polycyclic aromatic hydrocarbon is an ortho-position or a meta-position of a phenyl group constituting the second polycyclic aromatic hydrocarbon.

14. An organic semiconductor layer comprising:
a mixture of a first polycyclic aromatic hydrocarbon to which a first substituent R₁ other than a hydrogen atom is bonded by a single bond, and a second polycyclic aromatic hydrocarbon to which a second substituent R₂ other than a hydrogen atom is bonded by a single bond,
wherein the first polycyclic aromatic hydrocarbon and the second polycyclic aromatic hydrocarbon are formed from the same polycyclic aromatic hydrocarbon,
wherein a binding site of the first substituent R₁ to the first polycyclic aromatic hydrocarbon is the same as a binding site of the second substituent R₂ to the second polycyclic aromatic hydrocarbon, and
wherein the first substituent R₁ and the second substituent R₂ are different.

15. The organic semiconductor layer according to claim 14,
wherein the first polycyclic aromatic hydrocarbon and the second polycyclic aromatic hydrocarbon are formed from 3,9-diphenyl peri-xanthenoxanthene,
wherein the binding site of the first substituent R₁ to the first polycyclic aromatic hydrocarbon is a para-position of a phenyl group constituting the first polycyclic aromatic hydrocarbon, and
wherein the binding site of the second substituent R₂ to the second polycyclic aromatic hydrocarbon is a para-position of a phenyl group constituting the second polycyclic aromatic hydrocarbon.

16. The organic semiconductor layer according to claim 12,
wherein the first substituent R₁ is one kind of substituent selected from the group consisting of an alkyl group, a cycloalkyl group, an alkenyl group, an alkynyl group, an aryl group, an arylalkyl group, an aromatic heterocycle, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amide group, a carbamoyl group, a ureido group, a sulfinyl group, an alkylsulfonyl group, an arylsulfonyl group, an amino group, a halogen atom, a fluorinated hydrocarbon group, a cyano group, a nitro group, a hydroxy group, a mercapto group, and a silyl group, and
wherein the second substituent R₂ is one kind of substituent selected from the group consisting of a hydrogen atom, an alkyl group, a cycloalkyl group, an alkenyl group, an alkynyl group, an aryl group, an arylalkyl group, an aromatic heterocycle, a heterocyclic group, an alkoxy group, a cycloalkoxy group, an aryloxy group, an alkylthio group, a cycloalkylthio group, an arylthio group, an alkoxycarbonyl group, an aryloxycarbonyl group, a sulfamoyl group, an acyl group, an acyloxy group, an amide group, a carbamoyl group, a ureido group, a sulfinyl group, an alkylsulfonyl group, an arylsulfonyl group, an amino group, a halogen atom, a fluorinated hydrocarbon group, a cyano group, a nitro group, a hydroxy group, a mercapto group, and a silyl group.

17. An electronic device comprising at least:
a first electrode;
a second electrode disposed separately from the first electrode; and
an active layer provided from the first electrode to the second electrode,
wherein the active layer is formed from the organic semiconductor layer according to claim 1.

18. The electronic device according to claim 17, comprising:
a first electrode;
a second electrode disposed separately from the first electrode;
a control electrode; and
an insulating layer,
wherein the control electrode is provided facing a portion of an active layer that is positioned between the first electrode and the second electrode via the insulating layer.

19. A method for manufacturing an electronic device, the electronic device including at least
a first electrode,
a second electrode disposed separately from the first electrode, and
an active layer provided from the first electrode to the second electrode,
the method comprising:
forming the active layer by coating and drying
a mixed solution formed from a mixture of a first polycyclic aromatic hydrocarbon to which a substituent R₁ other than a hydrogen atom is bonded by a single bond and a second polycyclic aromatic hydrocarbon, or
a mixed solution formed from a mixture of a first polycyclic aromatic hydrocarbon to which a first substituent R₁ other than a hydrogen atom is bonded by a single bond and a second polycyclic aromatic hydrocarbon to which a second substituent R₂ other than a hydrogen atom is bonded by a single bond,
wherein the first polycyclic aromatic hydrocarbon and the second polycyclic aromatic hydrocarbon are formed from the same polycyclic aromatic hydrocarbon, and
wherein a binding site of the first substituent R₁ to the first polycyclic aromatic hydrocarbon is different to a binding site of the second substituent R₂ to the second polycyclic aromatic hydrocarbon, or
a mixed solution formed from a mixture of a first polycyclic aromatic hydrocarbon to which a first substituent R₁ other than a hydrogen atom is bonded by a single bond and a second polycyclic aromatic hydrocarbon to which a second substituent R₂ other than a hydrogen atom is bonded by a single bond,
wherein the first polycyclic aromatic hydrocarbon and the second polycyclic aromatic hydrocarbon are formed from the same polycyclic aromatic hydrocarbon,
wherein a binding site of the first substituent R₁ to the first polycyclic aromatic hydrocarbon is the same as a binding site of the second substituent R₂ to the second polycyclic aromatic hydrocarbon, and
wherein the first substituent R₁ and the second substituent R₂ are different.

20. The method for manufacturing an electronic device according to claim 19, wherein an organic insulating material is further mixed in the mixed solution.
